(19) United States
(12) Patent Application Publication
(10) Pub. No.: US 2024/0222067 A1
(43) Pub. Date: Jul. 4, 2024

(54) Method for Alignment Free Ion Column

(71) Applicant: FEI Company, Hillsboro, OR (US)

(72) Inventors: Radek Smolka, Brezina (CZ); Lukas Zabransky, Ricany (CZ); Branislav Straka, Brno (CZ); Marek Melichar, Brno (CZ)

(21) Appl. No.: 18/393,233

(22) Filed: Dec. 21, 2023

Related U.S. Application Data
(60) Provisional application No. 63/435,624, filed on Dec. 28, 2022.

(51) Int. Cl. H01J 37/244; H01J 37/10; H01J 37/24

(52) U.S. Cl. CPC H01J 37/244; H01J 37/10; H01J 37/24; H01J 2237/24578; H01J 2237/2826

(57) ABSTRACT

Disclosed herein are systems and methods for calibration of a charged particle beam microscope, including a source configured to generate a CPB comprising a plurality of charged particles having a known energy; at least one lens; a detector; and a controller. According to various disclosed embodiments, the controller may determine, based on a calibration characteristic, that the CPB microscope requires recalibration. Based on that determination, the controller may operate the source to generate a calibration CPB and configure the at least one lens to act as a charged particle mirror. The controller may receive data from the detector associated with the plurality of charged particles after reflecting off the charged particle mirror. The controller may then analyze the data from the detector and automatically recalibrate the CPB microscope based on calibration characteristics in the data from the detector.

### RELATED APPLICATIONS

This application claims priority to U.S. Provisional Application No. 63/435,624, filed Dec. 28, 2022, the entire content of which is incorporated herein by reference.

### FIELD

The present disclosure generally relates to the field of charged particle beam microscopes.

### SUMMARY

An electron microscope is a microscope that uses a beam of accelerated electrons as a source of illumination. Due the shorter wavelength of an electron (e.g., up to 100,000 times shorter than visible photons), electron microscopes have a higher resolving power than traditional light-based microscopes. Thus, they can reveal details of much smaller objects. Electron microscopes use shaped magnetic fields to form electron optical lens systems that are analogous to the glass lenses of an optical light microscope.

Generally, electron microscopes are used to investigate the structure of a wide range of biological and inorganic specimens including microorganisms, cells, large molecules, biopsy samples, metals, and crystals. The original form of an electron microscope is referred to as a Transmission Electron Microscope (TEM), which uses a high voltage electron beam to illuminate a specimen and create an image. Later Scanning Electron Microscopes (SEM) were introduced. SEMs produce images by probing a specimen with a focused electron beam, which is scanned across an area of a specimen (e.g., raster scanning).

Scientists and engineers in both academia and industry are constantly facing new challenges that require highly localized characterization of a wide range of samples and materials. The ongoing drive to improve the quality of these materials means that structural and compositional information at the nanoscale is frequently necessary. Thus, Focused Ion Beam Scanning Electron Microscopy (FIB-SEM) was created. In FIB-SEM, instruments generate exactly this kind of data by combining the precise sample modification of FIB with the high-resolution imaging of SEM.

Moreover, in some systems, dedicated software may allow a three-dimensional structure analysis of a specimen. Observation in an intermittent manner enables clear observation of the structure of any invisible area of the folded portion, interface state, and other matters. The obtained three-dimensional position information may also make it possible to calculate the surface area, which cannot generally be obtained by surface observations.

However, the ion/electron column may require regular re-alignments for maximum performance. Various factors may contribute to an ion column falling out of alignment, such as, for example, due to imperfections, inner and outer changes of conditions, contaminations, and the like. Generally, these alignments are time consuming operations. During the realignment process, it is not possible for the column to be used for its intended purpose. Thus, not only does realignment have a built-in time and money cost, but it also impacts ongoing research, further impacting a user. Thus, a solution is needed that reduces or eliminates the need for manual realignment of the microscope.

In a first aspect, a system for a charged-particle beam (CPB) system may include, a source configured to generate a charged particle beam comprising a plurality of charged particles having a known energy. The system may further include at least one lens, a charged particle detector, and a controller with a processor and computer readable instructions stored in a non-transitory memory. During operation, the controller may be configured to determine, based on a calibration characteristic, that the CPB microscope requires recalibration. Based on that determination, the controller may operate the source to generate a calibration CPB and configure at least one lens to act as a charged particle reflecting mirror. The charged particles are reflected off the mirror and captured by one or more detectors. The detectors then pass the received data over to the controller so that the controller can analyze the data and, if needed, automatically recalibrate the CPB microscope based on a pattern in the data from the detector.

In a second aspect, a method for operating a charged-particle beam (CPB) system may include determining, using a processor, that the CPB microscope requires recalibration based on a calibration characteristic. The processor may then enable a source to generate a calibration CPB comprising a plurality of charged particles having a known energy and enable at least one lens to act as a charged particle reflecting mirror. A detector is then used to detect the plurality of charged particles reflecting off the charged particle reflecting mirror. Once the detector data is collected, the processor may automatically recalibrate the CPB microscope based on the detected plurality of charged particles.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 provides a block diagram of an exemplary charged particle beam microscope system, in accordance with various embodiments.

FIGS. 2A and 2B provides an illustrative example image captured by a CPB microscope at an initial setup calibration, in accordance with various embodiments.

FIGS. 2C and 2D provides an illustrative example image captured by a CPB microscope after stigmation change, in accordance with various embodiments.

FIGS. 3A and 3B provides an illustrative example image captured by a CPB microscope at an initial setup calibration, in accordance with various embodiments.

FIGS. 3C and 3D provides an illustrative example image captured by a CPB microscope after beam shift, in accordance with various embodiments.

FIG. 4 provides diagrammatic representation of a charged particle beam (CPB) system 400, in accordance with various embodiments.

FIG. 5 provides a flow diagram of an example method of CPB microscope calibration, in accordance with various embodiments.

FIG. 6 provides a block diagram of an example computing device that may perform some or all the CPB microscope support methods disclosed herein, in accordance with various embodiments.

FIG. 7 provides a block diagram of an example CPB microscope support system in which some or all the CPB microscope support methods disclosed herein may be performed, in accordance with various embodiments.

### DETAILED DESCRIPTION

Disclosed herein are systems and methods for ion column alignment in charged particle beam microscopes and well as related methods. The section headings used herein are for organizational purposes only and are not to be construed as limiting the described subject matter in any way.

The microscope systems, according to the concepts disclosed herein, may achieve improved performance relative to conventional approaches. Various concepts may allow for alignment of the ion column(s) to run in the background (e.g., autonomously or without human input or intervention) when the column is not in use and without the need of specific test specimen. The concepts described herein relate to a technique where a charged particle beam is deflected (i.e., mirrored) inside the ion column by a reflective optical element back up the column, where the reflected image is used to determine and correct alignment issues with the beam. In some examples, the reflective optical element may be a lens (e.g., the final lens) operated in such a way that the lens becomes a mirror reflecting the beam. The reflected primary beam may then be scanned in raster pattern, mirrored by the reflective optical element and reflected to an in-column detector in order to determine beam parameters. As will be discussed further herein, the in-column detector may be a new detection surface or may be an existing element, such as, for example, one or more of the octupole plates.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the subject matter disclosed herein. However, the order of description should not be construed as to imply that these operations are necessarily order dependent. In particular, these operations may not be performed in the order of presentation. Operations described may be performed in a different order from the described embodiment. Various additional operations may be performed and/or described operations may be omitted in additional embodiments.

For the purposes of the present disclosure, the phrases “A and/or B” and “A or B” mean (A), (B), or (A and B). For the purposes of the present disclosure, the phrases “A, B, and/or C” and “A, B, or C” mean (A), (B), (C), (A and B), (A and C), (B and C), or (A, B, and C). Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices.

The description uses the phrases “an embodiment,” “various embodiments,” and “some embodiments,” each of which may refer to one or more of the same or different embodiments. Furthermore, the terms “comprising,” “including,” “having,” and the like, as used with respect to embodiments of the present disclosure, are synonymous. When used to describe a range of dimensions, the phrase “between X and Y” represents a range that includes X and Y. As used herein, an “apparatus” may refer to any individual device or collection of devices. The drawings are not necessarily to scale.

### I. Charged Particle Beam Microscope

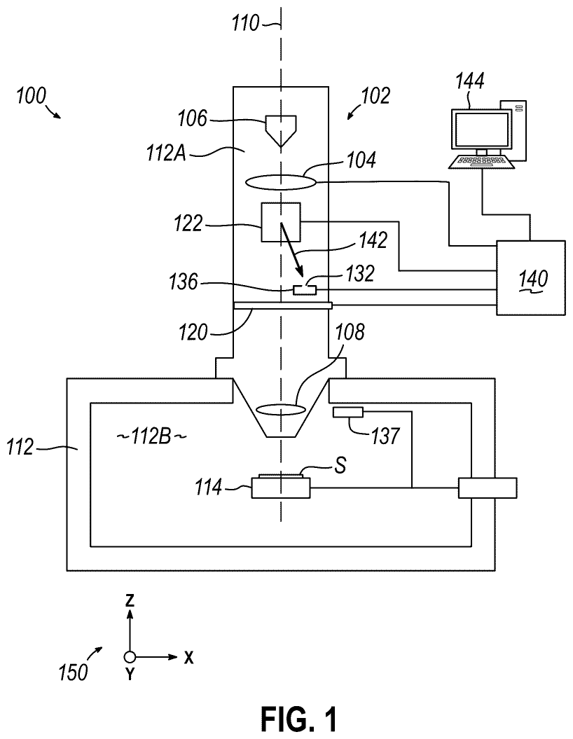

Referring now to FIG. 1, a representative embodiment of a charged particle beam (CPB) system 100 according to the concepts described herein is shown. CPB system 100 includes a CPB column 102 that directs a CPB along an optical axis 110 of the column 102 towards a sample S. The column 102 may at least include a condenser lens 104, a source 106 and an objective lens 108. The CPB source 106 may be, for example, a field emitter that produces an electron beam, but other sources can be used. In some embodiments, one or more additional CPB lenses can be provided. In general, all lenses may be magnetic lenses and/or electrostatic lenses. Typically, the CPB is aligned with a primary axis 110 during working mode, while performing sample processing or sample imaging. For example, during the working mode, the CPB propagates along the primary axis toward the sample when the beam deflector 122 is provided with the working deflection drive. In some examples, column 102 may be an electron column, e.g., a scanning electron microscope (SEM), but, in other examples, be a focused ion beam (FIB) column.

In some embodiments, the CPB system 100 may include a vacuum chamber 112 housing a movable specimen holder 114 for retaining a sample S. The vacuum chamber 112 can be evacuated using vacuum pumps (not shown) and typically defines a first volume 112A that contains the CPB source 106 and selected other CPB optical components and a second volume 112B that is situated to receive the sample S and the movable sample holder 114.

In a further embodiment, a column isolation valve (CIV) 120 may be situated, or configured, to separate the first volume 112A and the second volume 112B. Typically, the CIV 120 is operable to hermetically isolate the first volume 112A from the second volume 112B during specimen exchange. In some embodiments, the sample holder 114 can be movable (e.g., in an X-Y plane as shown with respect to a coordinate system 150, wherein a Y-axis is perpendicular to a plane of the drawing). In a further embodiment, the sample holder 114 can further move vertically (e.g., along a Z-axis) to compensate for variations in the height of the sample S. In some embodiments, the CPB microscope 102 can be arranged vertically above the sample S and can be used to image the sample S while an ion beam machines or otherwise processes the sample S.

As will be discussed further herein, in some embodiments, the CPB system 100 may include or be coupled to a computer processing apparatus 144 such as a control computer and a deflector controller 140 for controlling a beam deflector 122, CPB lenses 104, 108, and/or any other CPB lenses or components such as detectors and sample stages. The computer processing apparatus 144 can also control display of information gathered from or more CPB detectors on a display unit. In some cases, the computer processing apparatus 144 (e.g., the control computer) establishes various excitations, records image data, and controls operation of the CPB microscope 102.

During working mode, the propagation direction of a CPB beam from CPB source 106 may be adjusted by the deflector 122 (e.g., a charged plate such as 402 and 403) to propagate along the primary axis 110 for processing or imaging the specimen S on the specimen holder 114. In some embodiments, the beam deflector 122 may be a quadrupole or octupole beam deflector situated to provide CPB deflections along the X-axis and Y-axis. In some examples, additional beam alignment can be performed by beam measurements at or near the movable substrate holder 114.

In some embodiments, the CPB detector 136 may be a two-dimensional detector, or other position sensitive detector. The CPB detector may be a solid-state detector, scintillator with photodiode, photomultiplier, or microchannel plate. In other examples, a separate aperture plate can be used. A second CPB detector 137 may be situated within the second volume 112B or elsewhere to receive flux, such as scattered charged particles or secondary emission, in response to a CPB incident on the specimen S in the working mode of the microscope.

### II. Stigmation Change and Beam Shift

As discussed herein, due to various factors, such as, but not limited to, mechanical imperfections of the column, inner changes of conditions, outer changes of conditions, contamination, source position, and the like, the charged particle beam (CPB) system 100 may drift away from ideal calibration. In regular practice, a CPB system 100 typically needs realignment every two days. Generally, there are two primary examples of this drift, the first is known in the art, and referred to herein, as Stigmation Change. The second is known in the art, and referred to herein, as Beam Shift.

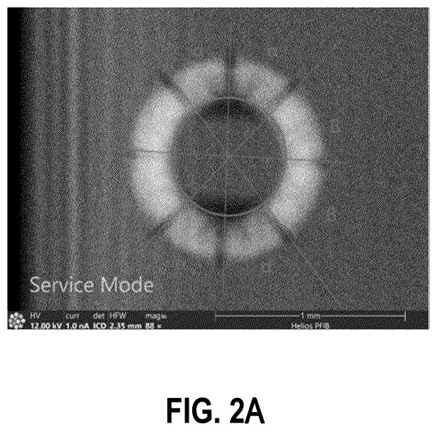

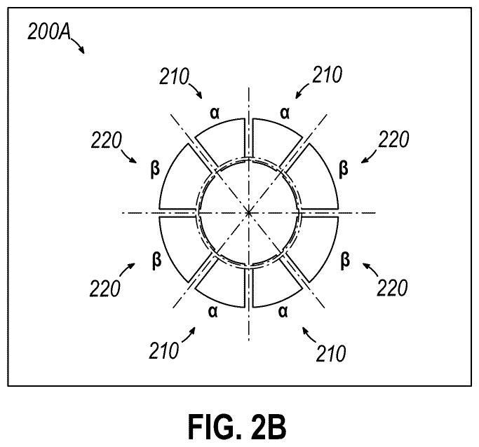

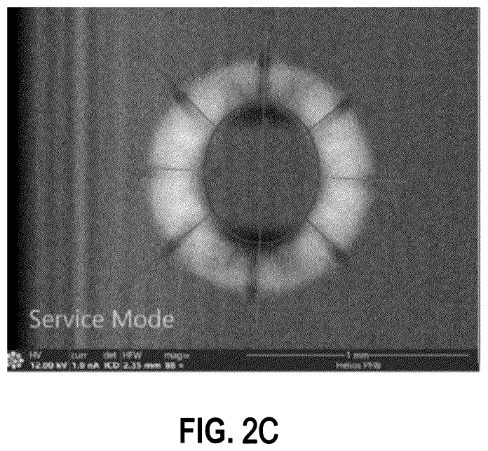

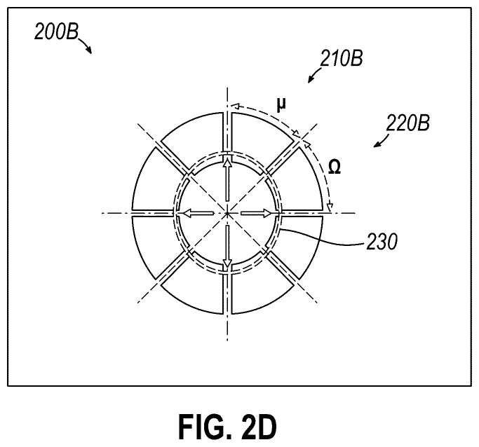

Referring now to FIGS. 2A, 2B, 2C and 2D an example of stigmation change is shown. In some embodiments, and as shown, the CPB system 100 may experience beam shift. An environmental change (e.g., a change in room temperature or humidity), movement of the CPB system (e.g., a bump of the instrument or location change), or other factor may cause the SEM focus to drift, and the FIB beam-pointing position relative to the specimen to change, potentially misaligning or damaging the sample and impairing the operation of the instrument.

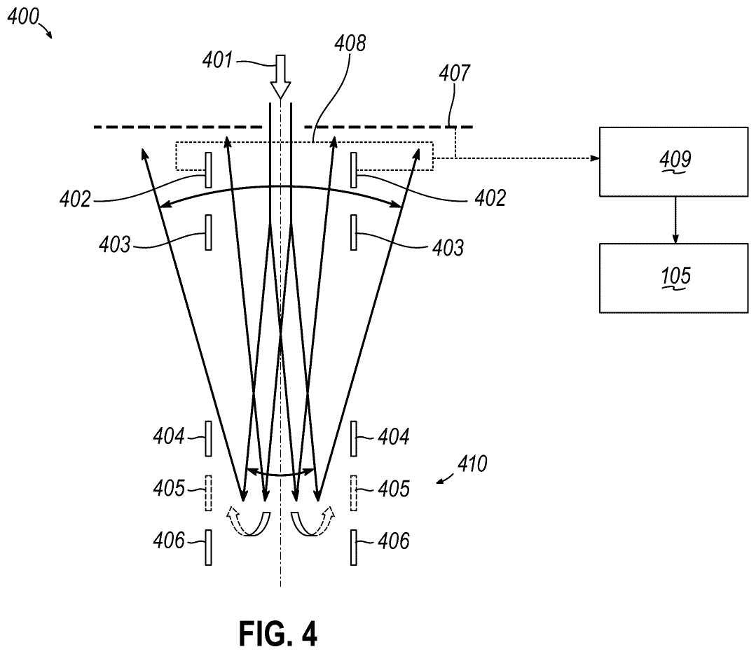

FIGS. 2A and 2B provide an illustrative example of a CPB system (e.g., 100) at an initial setup (i.e., aligned status). FIG. 2A is an internal image of the system, according to the concepts described herein, particularly with reference to FIG. 4, that shows the alignment characteristics of the CPB system. FIG. 2B is a line diagram illustrating the characteristics of FIG. 2A. As shown, particularly in FIG. 2A, the eight (8) bright regions represent eight (8) octupole plates. When the system is properly calibrated (e.g., as part of an initial setup of the system when the system has an aligned status), such as shown in FIGS. 2A and 2B, the angular spacing between corresponding segments of the octupole (e.g., 210 (“a”) and/or 220 (“B”)) are relatively evenly distributed. Stated differently, when system is properly calibrated (e.g., the stigmation is aligned), the eight plates will appear to be the same size, hence 210 (“a”) and/or 220 (“B”) should be generally the same. Alternatively, FIG. 2C provides an illustrative example of an image captured from the CPB system after stigmation change (a changed value of the stigmator), while FIG. 2D provides a line drawing illustrating the elements of FIG. 2C. In some embodiments, and as shown in FIGS. 2C and 2D, the stigmator shape 230 is skewed and the octupole images are rotated such that the original angles 210 and 220 have drifted to a new size/angle 210B and 220B.

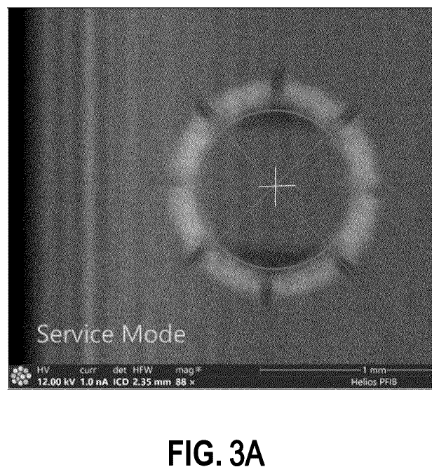

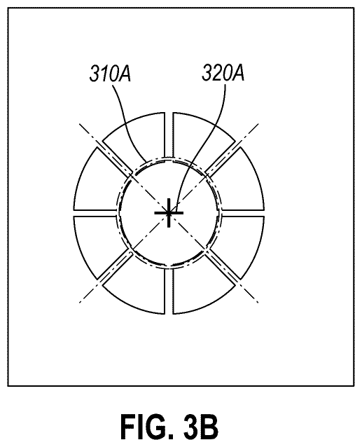

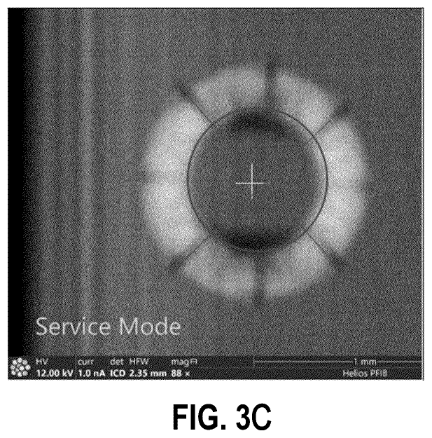

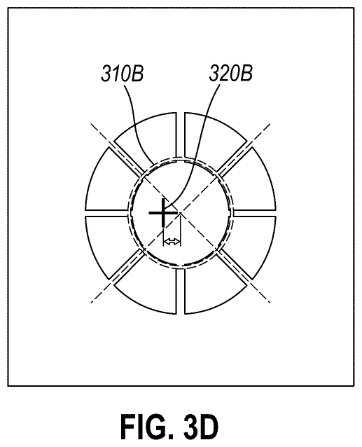

Referring now to FIGS. 3A, 3B, 3C and 3D, an example of beam shift is shown. As described with reference to FIGS. 2A through 2D, environmental change (e.g., a change in room temperature or humidity), movement of the CPB system (e.g., a bump of the instrument or location change), or other factor may cause the SEM focus to drift, and the FIB beam-pointing position relative to the specimen to change, potentially misaligning or damaging the sample and impairing the operation of the instrument.

Referring now to FIGS. 3A and 3B, an illustrative example of a CPB system (e.g., 100) at an initial setup (i.e., aligned and/or centered) is provided. When the CPB system 100 is properly calibrated, such as shown in FIGS. 3A and 3B, the alignment of beam target 340A is properly aligned over the target circle (e.g., the image of the octupole plates) 330A (i.e., the image is centered). Alternatively, FIG. 3C provides an illustrative example of an image captured by a CPB system after beam shift, while FIG. 3D is a line drawing illustrating the elements of FIG. 3C. In some embodiments, and as shown in FIGS. 3C and 3D, the beam target 340B has moved and is no longer properly centered on the target circle 330B (i.e., a changed value of quad where the center of the image is shifted). It should be understood that stigmation change and beam shift are two common ways a charged particle beam (CPB) system can fall out of calibration; however, the systems and methods disclosed herein are intended to be applicable to any factor that causes the CPB microscope to fall out of calibration. Thus, disclosed herein are systems and methods for addressing any type of calibration offset including but not limited to an alignment offset or a shape offset as shown but also other types of calibration such as aperture offset, quadrupole setup, or other calibration characteristic.

Thus, as discussed herein with reference to FIG. 1, a CPB system 100 may have a FIB lens-barrel (e.g., a column/lens assembly/tube) 102, an SEM column (not shown), or both, which periodically require re-alignment to maintain proper operation and accuracy. Current calibration methods require the use of a special calibration specimen, typically an ultra-flat silicon substrate having various pitch lines of known size/dimension/spacing. However, as noted above, current calibration methods are time consuming and costly both in materials and system uptime. The next section will provide a detailed analysis of how a CPB system (e.g., 100) may be calibrated without the use of a calibration specimen, without the need for operational downtime, and without requiring user interaction.

### III. Ion Detection System

Referring now to FIG. 4, a diagrammatic representation of a portion of a charged particle beam (CPB) system 400 according to the concepts described herein is shown. In some embodiments, the CPB system 400 is an example of a respective portion of a CPB system 100. CPB system 400 may have a source (e.g., a liquid metal ion source (LMIS)) (not shown) configured to generate a CPB comprising a plurality of ions having a known energy. Once the CPB is generated, it may then be inserted into the CPB system (e.g., via a suppressor) 401. In a further embodiment, the CPB (i.e., primary ions) may be controlled and/or guided along a desired path using one or more charged plates. By way of non-limiting example, the CPB system 400, may, as shown, have optical components 402

IV and 403. In some examples, optical component 402 may include a plurality of upper plates forming a multi-pole optical element (e.g., eight plates forming an octupole) Optical component 403 may likewise be formed from a plurality of electrodes forming a multi-pole optical element.

Thus, in some embodiments, and as shown, the charged particles may be contained within the instrument and controlled and directed to impact a desired target area, such as a sample S, where the trajectories of the charged particles are represented by the directional arrows. In a conventional CPB system, the charged particles pass though one or more focusing lenses, such as lens element 410 (formed from electrodes 404, 405 and 406), before reaching the sample S. In some embodiments, the excitation (e.g., thickness) of the charged particle lens 410 could be varied, and thus used for both magnification and focusing of an image to a certain image plain.

The operation of lens element 410 may also be used to focus/form an image. More specifically, when there is a spatial distribution of beam intensity in a plane, a lens can make a modified copy of the distribution in another plane along the direction of propagation. Thus, forming an image if/when all particles that leave a point in one plane and are mapped into another, regardless of their direction.

As discussed above, one of the abilities of a lens is to slow or reduce the speed of the electrons passing through the lens. A potential (e.g., voltage) may be applied to the lens to reduce the speed/ability of the charged particles to pass through the lens. Returning to FIG. 4, in some embodiments, and as shown, the CPB system 400 may include an upper electrode 404 (e.g., having a ground connection), a middle electrode 405 (e.g., having a charged connection), and a lower electrode 406 (e.g., having a ground connection). As described, the three electrodes 404, 405, and 406 may comprise a single lens element 410 with multiple layers or substrates. It should further be understood that the various embodiments may exist where more (e.g., 6, 9, etc.) or less (e.g., 1 or 2) than three electrodes are used and may form multiple lens elements.

Thus, in some embodiments, to form a reflective element, e.g., a mirror, and reflect the CPB back up the column, a current/voltage may be applied to the one or more electrodes (e.g., the middle electrode 405) to create a CPB reflector or mirror. Generally, and in accordance with various embodiments disclosed herein, for one or more lens elements to reflect all (e.g., 100%) of the charged particles, the potential applied to the one or more electrodes must be greater than the kinetic energy/charge ratio of the particles. In a further embodiment, the potential applied to the one or more lenses must also have the same polarity as the charge of the ion/particle.

By way of non-limiting example, if the charged particles being introduced to the system 401 have a kinetic energy of 14 keV, a voltage of 16 kV, or any value above 14 kV would need to be applied to the one or more lenses to reflect all the particles. Although positive voltage values are discussed herein, negative voltages may be used as well. Thus, in an embodiment where the ions are negatively charged, the voltage applied to the lens would also need to be negative (i.e., the lens must have the same polarity as the particle). Although reference has been made to one or more lenses, various alternative embodiments may exist where only a single lens has a charged applied or where multiple lenses have a charge applied.

Accordingly, in some embodiments, and as shown, the charged particles enter the CPB microscope at an entry point (e.g., an aperture of a source module). Once inside the CPB system 400, the CPB's trajectory is guided by one or more charged plates (e.g., 402 and 403) such that it transmits along an optical axis 401 and reaches at least one lens element 410 (electrodes 404, 405, and/or 406). The charged particles are then reflected (e.g., due to the reflecting electrodes having a higher potential than the kinetic energy/charge ratio of the particle) back to one or more detectors.

In some embodiments, and as shown, a detector 407 may be used. The detector 407 may be a new or additional component that is operatively coupled to or included in the CPB system. The detector 407 may receive some, or all, of the charged particles reflected off the excited electrodes (e.g., 404, 405, and/or 406) forming lens element 410. In a further embodiment, as the particles impact the detector 407, their impact signals are acquired and sent to a detection amplifier 409 before being processed by a processing device (e.g., 144 of FIG. 1). The processing device may, in some embodiments, create or facilitate the creation of a representative image of the impact location and intensity (e.g., based on the brightness of the image portion).

In an additional or alternative embodiment, one of the existing charged electrodes (e.g., 402, 403, or other plate) may be modified, or converted, to act as a detector represented by dashed line 408. The charged plate detector 408 may be an existing octupole in the CPB microscope. In this embodiment, similar to the dedicated detector, the plate detector 408 is impacted by some, or all, of the charged particles reflected off the electrodes (e.g., 404, 405, and/or 406) forming a reflective lens element 410.

Accordingly, in some embodiments, the CPB system may include, or be coupled to, an electrical relay (e.g., a mechanical relay, a solid-state relay, or any device capable of switching electrical inputs) which is operatively coupled to charged plates (e.g., the existing octupole). The relay toggles, or switches, the charged plates from functioning as a particle guide to a particle detector. In some embodiments, the relay may be controlled by a controller (e.g., processing device 144 of FIG. 1).

In another embodiment, once the particles impact a detector 408, the signal may be sent to a detection amplifier 409 before being processed by a processing device (e.g., 144 of FIG. 1). It should be understood that alternative embodiments may exist in which the detected data may not pass through a detection amplifier before being processed. Furthermore, alternative embodiments may exist wherein the detected data is passed through any number of processing tools (e.g., an amplifier, a filter, a conditioner, etc.) prior to being processed by the processing device 144.

Once the charged particles are received by a detector (e.g., the detector 407 or detector 408), the received data may be processed by a processing device 144 to determine if the CPB system 400 requires calibration. In an alternative embodiment, the received data may be processed by the processing device 144 to determine what adjustments are required to bring the CPB system 400 back into calibration.

By way of visual example, brief reference is made to FIGS. 2A, 2B, 3A, and 3B, which as discussed herein are illustrative example of two types of drift that can occur. Thus, as discussed herein, the processing device 144 may, in some embodiments, compare and/or contrast FIG. 2A (e.g., an ideal calibration image) against FIG. 2B (e.g., an image captured when the system is out of calibration) to determine what, if any, stigmation changes have occurred. Similarly, the processing device 144 may compare and/or contrast FIG. 3A (e.g., an ideal calibration image) against FIG. 3B (e.g., an image captured when the system is out of calibration) to determine what, if any, beam shifts have occurred. Accordingly, in some embodiments, the processing device 144 may determine s calibration parameters that can be applied to the electrode plates 402, 403 or lens electrodes 404, 405 and 406 to realign the CPB. Processing device 144 can consider one or more possible methods of alignment calibration characteristics (e.g., stigmation change, beam shift, aperture offset, quadrupole setup, etc.) that could result the CPB microscope being out of calibration and create an overall method to return the CPB microscope to proper calibration.

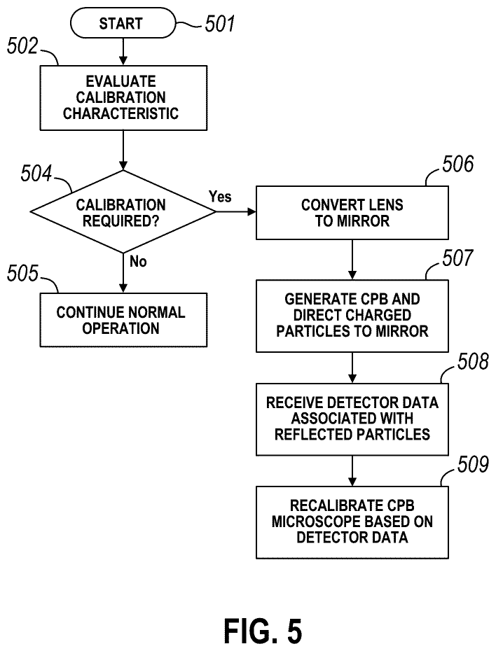

Referring now to FIG. 5, an illustrative flow diagram is shown in accordance with at least one embodiment. Thus, in some embodiments, and as shown, the system (e.g., the CPB System 400 and processing device 144) is initialized 501. Once the system is active, a preliminary evaluation 502 of a calibration characteristic may be carried out. For example, the system may, in some embodiments, need to perform steps 506, 507, and 508 to create the calibration characteristic data that is used in the evaluation 502. In an alternative embodiment, discussed in detail below, a preliminary evaluation 502 may not be automatically carried out and instead, the evaluation may be dependent on one or more calibration characteristics captured from prior (e.g., the most recent) calibration data.

In some embodiments, one or more calibration characteristics may be considered when determining if/when calibration should be evaluated. For example, in one embodiment, a calibration characteristic may be a temporal threshold characteristic. This could be, for example, a period of time that has passed since the prior evaluation 502. In a further embodiment, the temporal characteristic may relate to the amount of time the CPB microscope has been in use. In an additional or alternative embodiment, the calibration characteristic may be a usage threshold, such as, for example, exceeding a set number of uses, or exceeding set number of a particular usage type.

In a further embodiment, the determination 504 whether the alignment is needed may be done automatically during specific procedures (e.g., sample replacement, chamber pumping, initial startup, etc.) that don't require the work of the CPB. This is because, as discussed herein, calibration cannot be performed during the usage of the CPB beam. However, in some embodiments, calibration of a single beam (e.g., only electrons or only ions) may be possible in dual-beam system while the other beam is in use. Stated differently, ion beam alignment may be possible while using the electron beam system and vice versa.

In some embodiments, the calibration characteristics (e.g., temporal, usage, etc.) may be modifiable or adjustable. Accordingly, a particular user may be able to set their desired threshold levels for each calibration characteristic. In a further embodiment, a user may be able to remove existing characteristic thresholds entirely and/or create entirely new calibration characteristics.

Regardless of the trigger or threshold, once the calibration characteristics are evaluated 502, a determination is made regarding whether calibration is required 504. If calibration is not required, the CPB microscope simply continues 505 its normal operation. However, if calibration is required, as discussed herein, one or more lenses (e.g., 404, 405, and 406) are converted 506 to a mirror. The CPB is then introduced to the CPB microscope and the one or more charged plates (e.g., 402 and 403) are used to direct 507 the particles to the mirror. It should be understood that the flow diagram of FIG. 5 is for illustrative purpose only, and that alternative embodiments may exists. For example, in some embodiments, the CPB may be generated 507 prior to the lens being converted 506 into a mirror.

Once the particles of the CPB impact the mirror, the particles are reflected (as shown in FIG. 4) toward one or more detectors (e.g., a dedicated detector 407 and/or a plate detector 408). As discussed herein, various information associated with the detected particles are then received 507 by a processing device (e.g., 144), which evaluates the data to determine the type and/or magnitude of misalignment that results in the CPB microscope being out of calibration. Based on the evaluation, one or more components, such as one level of electrode plates 402 or 403, on the CPB microscope may be adjusted.

In some embodiments, the calibration adjustments may be automated (e.g., adjusting a current or voltage applied to one or more of the charged plates 402, 403), while in other embodiments, the system may prompt a user for assistance. Thus, in some embodiments, a processing device 144 may display on a display device a notification and/or a step-by-step process to guide the user during calibration. In one or more embodiments, the notification may be any of a visual notification, an auditory notification, a haptic notification, or the like.

In some embodiments, automatic recalibration 509 of the CPB microscope may be based on the particles detected 508 based on a comparison between the detected particles and an initial calibration data. Similar to FIGS. 2A, 2B, 3A, and 3B, a calibration offset may be calculated and utilized for recalibrating the CPB microscope.

As discussed herein, determining whether to initiate a calibration procedure may be based, at least in part, on exceeding one or more thresholds associated with a calibration characteristic (e.g., temporal or usage). However, in some embodiments, even if a threshold is met, a preliminary evaluation of the CPB microscope may be carried out.

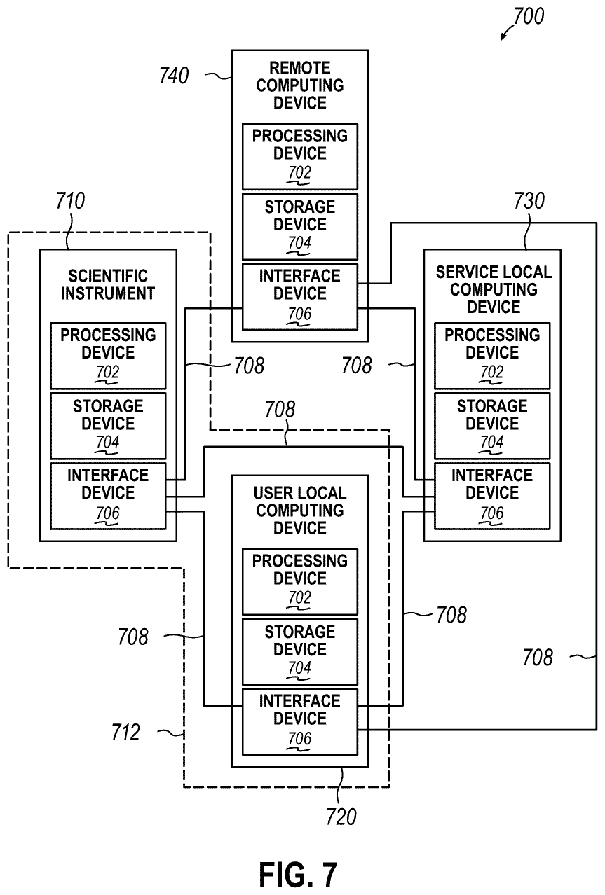

The CPB microscope methods disclosed herein may include interactions with a human user (e.g., via the user local computing device 720 discussed herein with reference to FIG. 7). These interactions may include providing information to the user (e.g., information regarding the operation of a scientific instrument such as the scientific instrument 710 of FIG. 7, information regarding a sample, or specimen, being analyzed or other test or measurement performed by a scientific instrument, information retrieved from a local or remote database, or other information) or providing an option for a user to input commands (e.g., to control the operation of a scientific instrument such as the scientific instrument 710 of FIG. 7, or to control the analysis of data generated by a scientific instrument), queries (e.g., to a local or remote database), or other information.

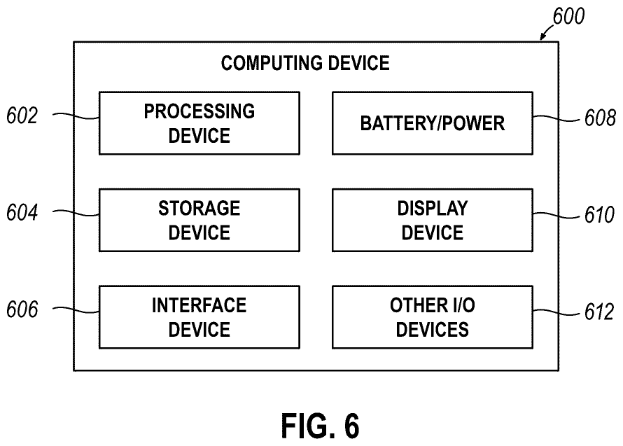

In some embodiments, the interactions with the CPB microscope system may be performed through a graphical user interface (GUI) that includes a visual display on a display device (e.g., the display device 610 discussed herein with reference to FIG. 6) that provides outputs to the user and/or prompts the user to provide inputs (e.g., via one or more input devices, such as a keyboard, mouse, trackpad, or touchscreen, included in the other I/O devices 612 discussed herein with reference to FIG. 6). The CPB microscope support systems disclosed herein may include any suitable GUIs for interaction with a user.

### IV. System Implementation

As noted above, the CPB system 400 may be implemented by one or more computing devices (e.g., processing device 144). FIG. 6 is a block diagram of a computing device 600 that may perform some or all of the CPB microscope support methods disclosed herein, in accordance with various embodiments. In some embodiments, the CPB system 400 may be implemented by a single computing device 600 or by multiple computing devices 600. Further, as discussed below, a computing device 600 (or multiple computing devices 600) that implements CPB system 400 may be part of one or more of the scientific instruments 710, the user local computing device 720, the service local computing device 730, or the remote computing device 740 of FIG. 7.

The computing device 600 of FIG. 6 is illustrated as having a number of components, but any one or more of these components may be omitted or duplicated, as suitable for the application and setting. In some embodiments, some or all the components included in the computing device 600 may be attached to one or more motherboards and enclosed in a housing (e.g., including plastic, metal, and/or other materials). In some embodiments, some these components may be fabricated onto a single system-on-a-chip (SoC) (e.g., an SoC may include one or more processing devices 602 and one or more storage devices 604). Additionally, in various embodiments, the computing device 600 may not include one or more of the components illustrated in FIG. 6, but may include interface circuitry (not shown) for coupling to the one or more components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 600 may not include a display device 610, but may include display device interface circuitry (e.g., a connector and driver circuitry) to which a display device 610 may be coupled.

The computing device 600 may include a processing device 602 (e.g., one or more processing devices). As used herein, the term “processing device” may refer to any device or portion of a device that processes electronic data from registers and/or memory to transform that electronic data into other electronic data that may be stored in registers and/or memory. The processing device 602 may include one or more digital signal processors (DSPs), application-specific integrated circuits (ASICs), central processing units (CPUs), graphics processing units (GPUs), crypto-processors (specialized processors that execute cryptographic algorithms within hardware), server processors, or any other suitable processing devices.

The computing device 600 may include a storage device 604 (e.g., one or more storage devices). The storage device 604 may include one or more memory devices. The computing device 600 may include one or more interfaces 606 (e.g., one or more interface devices 606). The interface device 606 may include circuitry for managing communications for the transfer of data to and from the computing device 600. The computing device 600 may include battery/power circuitry 608. The battery/power circuitry 608 may include one or more energy storage devices and/or circuitry for coupling components of the computing device 600 to an energy source separate from the computing device 600 (e.g., AC line power). The computing device 600 may include a display device or devices 610 and other input/output (I/O) devices 612.

One or more computing devices implementing any of the CPB microscope support modules or methods disclosed herein may be part of a CPB microscope support system. FIG. 7 is a block diagram of an example CPB microscope support system 700 in which some or all of the CPB microscope support methods disclosed herein may be performed, in accordance with various embodiments. The CPB microscope support modules and methods disclosed herein (e.g., the CPB system 400 of FIG. 4 and the method of FIG. 5) may be implemented by one or more of the scientific instruments 710, the user local computing device 720, the service local computing device 730, or the remote computing device 740 of the CPB microscope support system 700.

Any of the scientific instrument 710, the user local computing device 720, the service local computing device 730, or the remote computing device 740 may include any of the embodiments of the computing device 600 discussed herein with reference to FIG. 6, and any of the scientific instrument 710, the user local computing device 720, the service local computing device 730, or the remote computing device 740 may take the form of any appropriate ones of the embodiments of the computing device 600 discussed herein with reference to FIG. 6.

The scientific instrument 710, the user local computing device 720, the service local computing device 730, and the remote computing device 740 may be in communication with other elements of the CPB microscope support system 700 via communication pathways 708. The communication pathways 708 may communicatively couple the interface devices 706 of different ones of the elements of the CPB microscope support system 700, as shown, and may be wired or wireless communication pathways. The particular CPB microscope support system 700 depicted in FIG. 7 includes communication pathways between each pair of the scientific instrument 710, the user local computing device 720, the service local computing device 730, and the remote computing device 740, but this “fully connected” implementation is simply illustrative, and in various embodiments, various ones of the communication pathways 708 may be absent.

In some embodiments, a scientific instrument 710 may be sold by the manufacturer along with one or more associated user local computing devices 720 as part of a local scientific instrument computing unit 712. In some embodiments, different ones of the scientific instruments 710 included in a CPB microscope support system 700 may be different types of scientific instruments 710. In some such embodiments, the remote computing device 740 and/or the user local computing device 720 may combine data from different types of scientific instruments 710 included in a CPB microscope support system 700.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A charged-particle beam (CPB) system, comprising:
a source configured to produce a CPB comprising a plurality of charged particles;
at least one lens element formed from a plurality of electrodes, wherein the lens element is configured to operate as a mirror based on a voltage across at least one of the plurality of electrodes;
a detector element for generating calibration data from a received signal; and
a controller,
wherein calibration characteristics of the CPB system are determined by configuring the lens element to operate as the mirror, reflecting the CPB to the detector to generate the calibration data, and determining, using the controller, an alignment of the CPB system based on the calibration data.

2. The charged-particle beam (CPB) system of claim 1, wherein the controller is configured to recalibrate the CPB microscope based on the calibration data from the detector.

3. The charged-particle beam (CPB) system of claim 1, wherein the calibration characteristics are generated periodically based on time or usage between calibrations.

4. The charged-particle beam (CPB) system of claim 3, wherein the controller is configured to determine the alignment of the CPB system by comparing the calibration characteristics to known calibration data.

5. The charged-particle beam (CPB) system of claim 1, wherein the at least one lens comprises an upper electrode, a middle electrode, and a lower electrode.

6. The charged-particle beam (CPB) system of claim 1, wherein the detector comprises an existing octupole in the CPB microscope.

7. The charged-particle beam (CPM) system of claim 1, wherein the detector comprises one of the plurality of electrodes.

8. The charged-particle beam (CPB) system of claim 1, further comprising charge plates operable to control a path of the CPB.

9. The charged-particle beam (CPB) system of claim 8, wherein the alignment of the CPB system is adjusted by altering operation of the charge plates using the controller.

10. The charged-particle beam (CPM) system of claim 8, further comprising an electrical relay coupled to the charged plates, the electrical relay switching the charged plates from functioning as a particle guide to a particle detector.

11. The charged-particle beam (CPB) system of claim 1, wherein the controller is further configured to provide a notification to at least one user that the CPB system requires calibration based on the calibration data.

12. The charged-particle beam (CPM) system of claim 1, wherein the voltage is higher than a charge ratio of the plurality of charged particles.

13. The charged-particle beam (CPM) system of claim 1, wherein the voltage has the same polarity as a charge of the plurality of charged particles.

14. A method for operating a charged-particle beam (CPB) system, comprising:
determining, using a controller, that a CPB microscope requires recalibration based on a parameter of the CPB system;
enabling, using the controller, a source to generate a CPB comprising a plurality of charged particles;
configuring, using the controller, at least one lens element to act as a charged particle mirror;
receiving at a detector the plurality of charged particles reflecting from the charged particle mirror to produce calibration data;
processing the calibration data using the controller to determine calibration characteristics of the CPB system; and
recalibrating, using the controller, the CPB system based on the calibration characteristics.

15. The method of claim 14, wherein the at least one lens element is formed from a plurality of electrodes.

16. The method of claim 15, wherein configuring the at least one lens element to act as the charged particle mirror comprises applying a voltage across at least one of the plurality of electrodes, the voltage higher than a charge ratio of the plurality of charged particles.

17. The method of claim 15, wherein configuring the at least one lens element to act as the charged particle mirror comprises applying a voltage across a middle electrode of the plurality of electrodes.

18. The method of claim 14, wherein the calibration characteristics are generated periodically based on time or usage between calibrations.

19. The method of claim 14, wherein the detector comprises charged particle receptors in the CPB microscope.

20. The method of claim 14, wherein the detector comprises an existing octupole in the CPB microscope.
